(19) United States
(12) Patent Application Publication
(10) Pub. No.: US 2026/0101658 A1
(43) Pub. Date: Apr. 9, 2026

(54) DISPLAY PANEL, ELECTRONIC DEVICE INCLUDING THE SAME AND METHOD OF MANUFACTURING DISPLAY PANEL

(71) Applicant: Samsung Display Co., Ltd., Yongin-si (KR)

(72) Inventors: Daeho SONG, Yongin-si (KR); Miyeon CHO, Yongin-si (KR); Yehwan CHOI, Yongin-si (KR)

(21) Appl. No.: 19/285,795

(22) Filed: Jul. 30, 2025

(30) Foreign Application Priority Data
Oct. 7, 2024 (KR) 10-2024-0136037

(51) Int. Cl. H10K 59/80; H10K 59/12; H10K 59/122; H10K 59/131; H10K 102/10

(52) U.S. Cl. CPC H10K 59/8051; H10K 59/1201; H10K 59/122; H10K 59/131; H10K 59/878; H10K 2102/101

(57) ABSTRACT

Provided is a display panel. The display panel includes a complementary metal oxide semiconductor (CMOS) circuit substrate including a semiconductor substrate, and a wiring layer above the semiconductor substrate, and including a conductive pattern, a base insulation layer above the conductive pattern, and a reflective conductive pattern connected to the conductive pattern through a contact opening penetrating the base insulation layer, a first light-emitting element above the CMOS circuit substrate, and including a first electrode contacting the reflective conductive pattern, a second electrode above the first electrode, and an emission unit between the first electrode and the second electrode, and a pixel definition layer above the wiring layer, and defining an opening exposing the first electrode and having a width at an upper surface of the first electrode that is less than a width of the contact opening at an upper surface of the base insulation layer.

### CROSS-REFERENCE TO RELATED APPLICATION

The present application claims priority to, and the benefit of, Korean Patent Application No. 10-2024-0136037, filed on Oct. 7, 2024, in the Korean Intellectual Property Office, the entire disclosure of which is incorporated herein by reference.

### BACKGROUND

The present disclosure herein relates to a display panel including a semiconductor substrate, an electronic device including the same, and a method of manufacturing a display panel.

Electronic devices, which provide an image to a user, such as smartphones, laptop computers, car navigation systems, and smart televisions, include a display device for displaying an image. Augmented reality devices, virtual reality devices, or video projection devices may include a micro display device. The micro display device may include a CMOS wafer and a light-emitting element located on the CMOS wafer to display an image with high luminance while being driven at low power.

### SUMMARY

The present disclosure provides a display panel including a light-emitting element with a simplified electrode structure.

The present disclosure also provides an electronic device including the display panel.

The present disclosure also provides a method of manufacturing the display panel.

One or more embodiments of the present disclosure provides a display panel including a complementary metal oxide semiconductor (CMOS) circuit substrate including a semiconductor substrate, and a wiring layer above the semiconductor substrate, and including a conductive pattern, a base insulation layer above the conductive pattern, and a reflective conductive pattern connected to the conductive pattern through a contact opening penetrating the base insulation layer, a first light-emitting element above the CMOS circuit substrate, and including a first electrode contacting the reflective conductive pattern, a second electrode above the first electrode, and an emission unit between the first electrode and the second electrode, and a pixel definition layer above the wiring layer, and defining an opening exposing the first electrode and having a width at an upper surface of the first electrode that is less than a width of the contact opening at an upper surface of the base insulation layer.

The first electrode may contact an upper surface of the base insulation layer.

The first electrode may include a transparent conductive oxide pattern.

A width of a lower surface of the first electrode may be greater than the width of the contact opening, wherein an upper surface of the reflective conductive pattern is inside the first electrode in plan view.

An upper surface of the reflective conductive pattern may be substantially level with an upper surface of the base insulation layer.

The display panel may further include a barrier layer between the reflective conductive pattern and an inner surface of the base insulation layer defining the contact opening, wherein the barrier layer includes a barrier metal layer and a barrier metal nitride layer.

The barrier metal layer may include titanium or tantalum.

The barrier layer may be not on an upper surface of the base insulation layer.

The reflective conductive pattern may include silver.

The pixel definition layer may include a first inorganic layer, a second inorganic layer including a different material from the first inorganic layer, and a third inorganic layer above the second inorganic layer, including a different material from the second inorganic layer, and extending further than the second inorganic layer in plan view to define a tip structure.

The pixel definition layer and the base insulation layer may define a trench or a slit outside the first electrode in plan view.

The trench or the slit may have a closed line shape in plan view.

The emission unit may include a first light-emitting layer configured to generate first color light, a first charge generation layer above the first light-emitting layer, a second light-emitting layer above the first charge generation layer, and configured to generate second color light, a second charge generation layer above the second light-emitting layer, and a third light-emitting layer above the second charge generation layer, and configured to generate third color light.

The display panel may further include a second light-emitting element above the CMOS circuit substrate, and including a first electrode spaced from the first electrode of the first light-emitting element, an emission unit integrated with the emission unit of the first light-emitting element, and a second electrode integrated with the second electrode of the first light-emitting element.

The display panel may further include a thin-film encapsulation layer above the first light-emitting element, a color filter above the thin-film encapsulation layer, and a lens above the color filter.

A source region and a drain region may be defined in the semiconductor substrate, wherein the wiring layer includes a gate above the semiconductor substrate between the source region and the drain region in plan view, at least one insulation layer above the gate, and at least one contact electrode connected to the source region or to the drain region through a contact hole in the at least one insulation layer.

In one or more embodiments of the present disclosure, a method of manufacturing a display panel may include forming a contact opening in a base insulation layer, forming a reflective conductive layer inside the contact opening above an upper surface of the base insulation layer, performing chemical-mechanical polishing to form a reflective conductive pattern inside the contact opening and not on the upper surface of the base insulation layer, forming a first electrode above the upper surface of the base insulation layer, and forming a pixel definition layer above the upper surface of the base insulation layer and defining an opening exposing a portion of the first electrode, the opening having a width at an upper surface of the first electrode that is less than a width of the contact opening at an upper surface of the base insulation layer.

The forming of the contact opening may include forming a cavity in the base insulation layer, and forming a contact hole from the cavity and penetrating the base insulation layer, the contact hole having a width that is less than a width of the cavity.

The method may further include forming a barrier layer including a barrier metal layer and a barrier metal nitride layer above the upper surface of the base insulation layer and an inner surface of the base insulation layer defining the contact opening, wherein the performing of chemical-mechanical polishing includes removing a portion of the barrier layer above the upper surface of the base insulation layer.

In one or more embodiments of the present disclosure, an electronic device may include a display panel, a frame accommodating the display panel, and a structure on which the frame is mounted, wherein the display panel includes a complementary metal oxide semiconductor (CMOS) circuit substrate including a semiconductor substrate, and a wiring layer above the semiconductor substrate and including a conductive pattern, a base insulation layer on the conductive pattern, and a reflective conductive pattern connected to the conductive pattern through a contact opening in the base insulation layer, a first light-emitting element above the CMOS circuit substrate, and including a first electrode contacting the reflective conductive pattern, a second electrode above the first electrode, and an emission unit between the first electrode and the second electrode, and a pixel definition layer above the wiring layer, and defining an opening exposing the first electrode and having a width at an upper surface of the first electrode that is less than a width of the contact opening at an upper surface of the base insulation layer.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is a block diagram of an electronic device according to one or more embodiments of the present disclosure;

FIG. 1B is a perspective view of an electronic device according to one or more embodiments of the present disclosure;

FIG. 2 is a perspective view of a display panel according to one or more embodiments of the present disclosure;

FIG. 3 is a cross-sectional view of a display panel according to one or more embodiments of the present disclosure;

FIG. 4A is a plan view of a display region according to one or more embodiments of the present disclosure;

FIG. 4B is a cross-sectional view of a display region according to one or more embodiments of the present disclosure;

FIG. 4C is a cross-sectional view of a light-emitting element according to one or more embodiments of the present disclosure;

FIGS. 5A and 5B are enlarged partial cross-sectional views of a display panel according to one or more embodiments of the present disclosure; and

FIGS. 6 to 14 are cross-sectional views illustrating a method of manufacturing a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

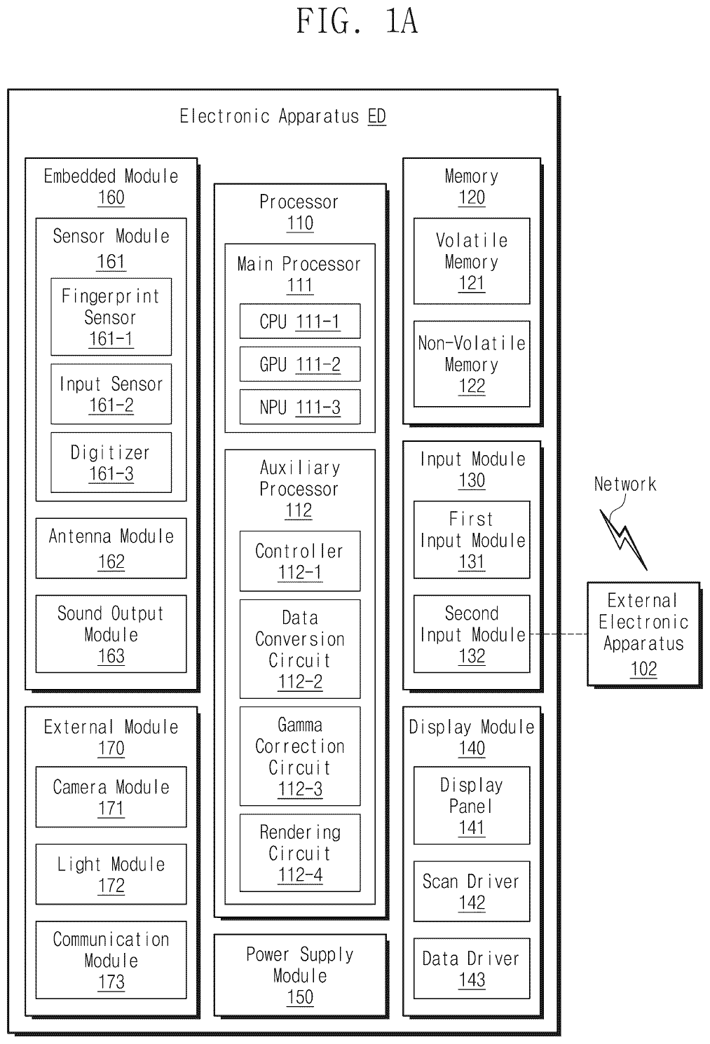

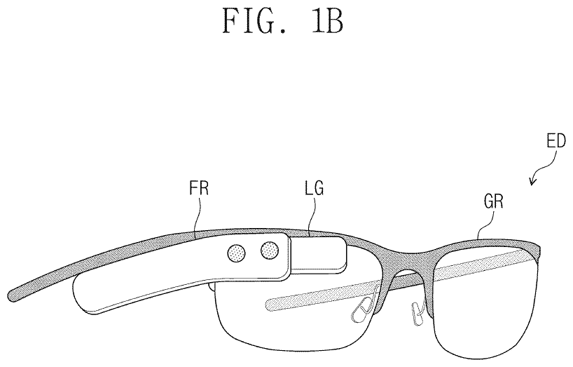

FIG. 1A is a block diagram of an electronic device ED according to one or more embodiments of the present disclosure. FIG. 1B is an exploded perspective view of an electronic device ED according to one or more embodiments of the present disclosure.

The electronic device ED according to one or more embodiments of the present disclosure includes a display module 140. As illustrated in FIG. 1A, the electronic device ED outputs various pieces of information through the display module 140 within an operation system. When a processor 110 executes an application stored in a memory 120, the display module 140 provides application information to a user through a display panel 141.

The processor 110 acquires an external input through an input module 130 or a sensor module 161, and executes an application corresponding to the external input. For example, when a user chooses a camera icon displayed on the display panel 141, the processor 110 acquires a user's input through an input sensor 161-2, and activates a camera module 171. The processor 110 transmits, to the display module 140, image data corresponding to a captured image acquired by the camera module 171. The display module 140 may display an image corresponding to the captured image through the display panel 141.

As another example, when personal information authentication is executed in the display module 140, a fingerprint sensor 161-1 acquires, as input data, fingerprint information that has been input. The processor 110 compares the input data acquired through the fingerprint sensor 161-1 with authentication data stored in the memory 120, and executes an application according to the result of comparison.

The display module 140 may display, through the display panel 141, information executed according to the logic of the application.

As another example, when a music streaming icon displayed on the display module 140 is chosen, the processor 110 acquires a user's input through the input sensor 161-2, and activates a music streaming application stored in the memory 120. When a music execution command is input in the music streaming application, the processor 110 activates a sound output module 163 and provides, to the user, sound information corresponding to the music execution command.

In the above, an operation of the electronic device ED has been briefly described. Components of the electronic device ED will be described in detail below. Some of the components of the electronic device ED to be described below may be integrated and provided as a single component, and one component may be divided into two or more components.

Referring to FIG. 1A, the electronic device ED may communicate with an external electronic device 102 through a network (for example, a short-range wireless communication network or long-distance wireless communication network). According to one or more embodiments, the electronic device ED may include the processor 110, the memory 120, the input module 130, the display module 140, a power supply module 150, an embedded module 160, and an external module 170. According to one or more embodiments, at least one of the aforementioned components of the electronic device ED may be omitted, or one or more other components may be added. According to one or more embodiments, some components (for example, the sensor module 161, an antenna module 162, or the sound output module 163) among the aforementioned components may be integrated into another component (for example, the display module 140).

The processor 110 may execute software to control at least one other component (for example, a hardware or software component), of the electronic device ED, which is connected to the processor 110, and may perform various types of data processing or computations. According to one or more embodiments, as at least part of the data processing or computations, the processor 110 may store data or a command received from other components (for example, the input module 130, the sensor module 161, or a communication module 173) in a volatile memory 121, may process the command or data stored in the volatile memory 121, and result data may be stored in a non-volatile memory 122.

The processor 110 may include a main processor 111 and an auxiliary processor 112. The main processor 111 may include at least one of a central processing unit (CPU) 111-1 or an application processor (AP). The main processor 111 may further include at least any one among a graphic processing unit (GPU) 111-2, a communication processor (CP), and an image signal processor (ISP). The main processor 111 may further include a neural processing unit (NPU) 111-3. The neural processing unit may be a processor specialized in processing an artificial intelligence model, and the artificial intelligence model may be generated through machine learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more thereof, but is not limited to the above examples. The artificial intelligence model may additionally or generally include a software structure in addition to a hardware structure. At least two among the aforementioned processing units and the processors may be implemented as one integrated component (for example, a single chip) or may be respectively implemented as individual components (for example, a plurality of chips).

The auxiliary processor 112 may include a controller 112-1. The controller 112-1 may include an interface conversion circuit and a timing control circuit. The controller 112-1 may receive an image signal from the main processor 111, may convert a data format of the image signal to comply with an interface specification for the display module 140, and then output image data. The controller 112-1 may output various control signals that are necessary to drive the display module 140.

The auxiliary processor 112 may further include a data conversion circuit 112-2, a gamma correction circuit 112-3, a rendering circuit 112-4, and the like. The data conversion circuit 112-2 may receive the image data from the controller 112-1, and may compensate for the image data to display an image having a desired luminance according to the properties of the electronic device ED, a user's setting, or the like, or may convert the image data for reduction in power consumption, compensation for afterimage, or the like. The gamma correction circuit 112-3 may convert the image data, a gamma reference voltage, or the like such that the image displayed in the electronic device ED has a desired gamma property. The rendering circuit 112-4 may receive the image data from the controller 112-1, and may render the image data in consideration of a pixel arrangement, etc., of the display panel 141 applied to the electronic device ED. At least one of the data conversion circuit 112-2, the gamma correction circuit 112-3, or the rendering circuit 112-4 may be integrated into another component (for example, the main processor 111 or the controller 112-1). At least one of the data conversion circuit 112-2, the gamma correction circuit 112-3, or the rendering circuit 112-4 may also be integrated into a data driver 143 to be described later.

The memory 120 may store various data used by at least one component (for example, the processor 110 or the sensor module 161) of the electronic device ED, and may store input data or output data about commands related thereto. The memory 120 may include at least one of the volatile memory 121 or the non-volatile memory 122.

The input module 130 may receive commands or data, which will be used in a component (for example, the processor 110, the sensor module 161, or the sound output module 163) of the electronic device ED, from the outside (for example, a user or the external electronic device 102) of the electronic device ED.

The input module 130 may include a first input module 131 to which commands or data are input from a user and a second input module 132 to which commands or data are input from the external electronic device 102. The first input module 131 may include a microphone, a mouse, a keyboard, a key (for example, a button) or a pen (for example, a passive pen or an active pen). The second input module 132 may support a designated protocol that allows wired or wireless connection with the external electronic device 102. According to one or more embodiments, the second input module 132 may include a high-definition multimedia interface (HDMI), a universal serial bus (USB) interface, an SD card interface, or an audio interface. The second input module 132 may include a connector, for example, a HDMI connector, a USB connector, an SD card connector, or an audio connector (for example, a headphone connector), which is capable of physical connection with the external electronic device 102.

The display module 140 visually provides information to a user. The display module 140 may include a display panel 141, a scan driver 142, and a data driver 143. The display module 140 may further include a window, a chassis, and a bracket for protecting the display panel 141.

The display panel 141 may include a liquid crystal display panel, an organic light-emitting display panel, or an inorganic light-emitting display panel, and a type of the display panel 141 is not particularly limited. The display panel 141 may be a rigid display panel, or a flexible display panel that is rollable or foldable. The display module 140 may further include a supporter for supporting the display panel 141, a bracket, a heat dissipation member, or the like.

The scan driver 142 may be mounted as a driving chip on the display panel 141. In addition, the scan driver 142 may be integrated into the display panel 141. For example, the scan driver 142 may include an amorphous silicon TFT gate (ASG) driver circuit, a low temperature polycrystalline silicon (LTPS) TFT gate driver circuit, or an oxide semiconductor TFT gate (OSG) driver circuit, which is integrated in the display panel 141. The scan driver 142 receives a control signal from the controller 112-1, and outputs scans signal to the display panel 141 in response to the control signal.

The display panel 141 may further include an emission driver. The emission driver outputs an emission control signal to the display panel 141 in response to the control signal received from the controller 112-1. The emission driver may be formed separately from the scan driver 142, or may be integrated into the scan driver 142.

The data driver 143 receives the control signal from the controller 112-1, converts the image data into an analog voltage (for example, a data voltage) in response to the control signal, and then outputs data voltages to the display panel 141.

The data driver 143 may be integrated into another component (for example, the controller 112-1). The functions of the interface conversion circuit and the timing control circuit of the aforementioned controller 112-1 may also be integrated into the data driver 143.

The display module 140 may further include an emission driver, a voltage generation circuit, and the like. The voltage generation circuit may output various voltages that are necessary to drive the display panel 141.

The power supply module 150 supplies power to the components of the electronic device ED. The power supply module 150 may include a battery for charging a power voltage. The battery may include a non-rechargeable primary cell, a rechargeable secondary cell, or a fuel cell. The power supply module 150 may include a power management integrated circuit (PMIC). The PMIC supplies optimized power to each of the aforementioned modules and modules to be described later. The power supply module 150 may include a wireless power transmission and reception member that is electrically connected to the battery. The wireless power transmission and reception member may include a plurality of antenna radiators in a coil shape.

The electronic device ED may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may sense an input applied by a part of the user body or an input applied by a pen of the first input module 131, and may generate an electrical signal or a data value corresponding to the input. The sensor module 161 may include at least any one among the fingerprint sensor 161-1, the input sensor 161-2, and/or a digitizer 161-3.

The fingerprint sensor 161-1 may generate a data value corresponding to a user's fingerprint. The fingerprint sensor 161-1 may include any one of an optical fingerprint sensor or a capacitive fingerprint sensor.

The input sensor 161-2 may generate a data value corresponding to coordinate information about the input applied by the pen or the input applied by a part of the user body. The input sensor 161-2 may generate, as the data value, an amount of change in capacitance caused by the input. The input sensor 161-2 may sense an input applied by the passive pen, or may transmit/receive data to/from the active pen.

The input sensor 161-2 may also measure bio-signals such as blood pressure, hydration, or body fat. For example, when a user does not move during a certain period of time while touching a sensor layer or a sensing panel with a part of the user body, the input sensor 161-2 may sense the bio-signals on the basis of changes in electric field caused by the part of the user body, and output, to the display module 140, information desired by the user.

The digitizer 161-3 may generate a data value corresponding to coordinate information about the input applied by the pen. The digitizer 161-3 may generate, as the data value, an amount of electromagnetic change caused by the input. The digitizer 161-3 may sense an input applied by the passive pen, or may transmit/receive data to/from the active pen.

At least one among the fingerprint sensor 161-1, the input sensor 161-2, and the digitizer 161-3 may also be implemented as a sensor layer formed on the display panel 141 through a continuous process. The fingerprint sensor 161-1, the input sensor 161-2, and the digitizer 161-3 may be located on/over the display panel 141, and any one among the fingerprint sensor 161-1, the input sensor 161-2, and/or the digitizer 161-3, for example, the digitizer 161-3 may be located under the display panel 141.

At least two among the fingerprint sensor 161-1, the input sensor 161-2, and the digitizer 161-3 may be formed to be integrated into a single sensing panel through the same process. When integrated into the single sensing panel, the sensing panel may be located between the display panel 141 and a window located on/over the display panel 141. According to one or more embodiments, the sensing panel may also be located on the window, and the location of the sensing panel is not particularly limited.

At least one among the fingerprint sensor 161-1, the input sensor 161-2, and the digitizer 161-3 may be embedded in the display panel 141. That is, at least one among the fingerprint sensor 161-1, the input sensor 161-2, and the digitizer 161-3 may be concurrently or substantially simultaneously formed through a process for forming elements (for example, a light-emitting element, a transistor, or the like) included in the display panel 141.

In addition, the sensor module 161 may generate an electrical signal or a data value corresponding to an internal state or an external state of the electronic device ED. For example, the sensor module 161 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 162 may include one or more antennae for transmitting a signal or power to the outside or receiving a signal or power from the outside. According to one or more embodiments, the communication module 173 may transmit a signal to the external electronic device, or receive a signal from the external electronic device through an antenna suitable for a communication method. An antenna pattern of the antenna module 162 may be integrated into one component (for example, the display panel 141) of the display module 140, the input sensor 161-2, or the like.

The sound output module 163 may be a unit for outputting a sound signal to the outside of the electronic device ED, and for example, may include a speaker that is used for general purposes such as multimedia playback or recording playback, and a receiver that is used exclusively for receiving phone calls. According to one or more embodiments, the receiver may be formed integrally with or separately from the speaker. A sound output pattern of the sound output module 163 may be integrated into the display module 140.

The camera module 171 may capture still images and moving images. According to one or more embodiments, the camera module 171 may include one or more lenses, an image sensor, or an image signal processor. The camera module 171 may further include an infrared camera capable of measuring presence/absence of a user, a user's location, user's gaze, and the like.

The light module 172 may provide light. The light module 172 may include a light-emitting diode or a xenon lamp. The light module 172 may operate in conjunction with, or may operate independently from, the camera module 171.

The communication module 173 may assist in establishment of a wired or wireless communication channel between the electronic device ED and the external electronic device 102, and may assist in communication through the established communication channel. The communication module 173 may include any one among a wireless communication module, such as a cellular communication module, a short-range wireless communication module, or a global navigation satellite system (GNSS) communication module and a wired communication module such as a local area network (LAN) communication module or a power line communication module, or may include both the wireless communication module and the wired communication module. The communication module 173 may communicate with the external electronic device 102 through a short-range communication network such as Bluetooth® (Bluetooth® being a registered trademark of Bluetooth Sig, Inc., Kirkland, WA), Wi-Fi® direct (Wi-Fi® being a registered trademark of the non-profit Wi-Fi Alliance), or infrared data association (IrDA), or through a long-distance communication network such as a cellular network, Internet, or a computer network (for example, LAN or WAN). Various types of the communication modules 173 described above may be implemented as a single chip or may be respectively implemented as individual chips.

The input module 130, the sensor module 161, the camera module 171, and the like may be used for controlling the operation of the display module 140 in conjunction with the processor 110.

The processor 110 outputs commands or data to the display module 140, the sound output module 163, the camera module 171, or the light module 172, based on the input data received from the input module 130. For example, the processor 110 may generate image data corresponding to the input data applied through the mouse, the active pen, or the like and output the image data to the display module 140, or may generate command data corresponding to the input data and output the command data to the camera module 171 or the light module 172. When the input data are not received for a certain period of time from the input module 130, the processor 110 may switch an operation mode of the electronic device ED to a low power mode or a sleep mode, thereby reducing power consumed in the electronic device ED.

The processor 110 outputs commands or data to the display module 140, the sound output module 163, the camera module 171, or the light module 172, based on sensing data received from the sensor module 161. For example, the processor 110 may compare authentication data applied by the fingerprint sensor 161-1 with the authentication data stored in the memory 120, and then execute an application according to the result of comparison. The processor 110 may execute a command or output the corresponding image data to the display module 140 based on the sensing data detected by the input sensor 161-2 or the digitizer 161-3. When the temperature sensor is included in the sensor module 161, the processor 110 may receive temperature data about the temperature measured by the sensor module 161, and may further perform luminance correction, etc., on the image data based on the temperature data.

The processor 110 may receive measured data about presence/absence of a user, a user's location, user's gaze, or the like from the camera module 171. The processor 110 may further perform luminance correction, etc., on the image data based on the measured data. For example, the processor 110, which has determined the presence or absence of a user through the input from the camera module 171, may output image data with corrected luminance to the display module 140 through the data conversion circuit 112-2 or the gamma correction circuit 112-3.

Some components of the above components may be connected to each other through a communication method between peripheral devices, for example, a bus, general purpose input/output (GPIO), a serial peripheral interface (SPI), a mobile industry processor interface (MIPI), or an ultra path interconnect (UPI) link, and may mutually exchange signals (for example, commands or data). The processor 110 may communicate with the display module 140 through a mutually agreed-upon interface, and for example, any one of the aforementioned communication methods may be used. The present disclosure is not limited to the aforementioned communication methods.

The electronic device ED according to one or more embodiments of the present disclosure may be various types or forms of apparatuses. For example, the electronic device ED may include at least one of a portable communication device (for example, a smart phone), a tablet device, a portable multimedia device, a wearable device, or a home appliance device. The electronic device ED according to one or more embodiments of the present disclosure is not limited to the aforementioned devices. Some of the components of the electronic device ED described with reference to FIG. 1A may be omitted depending on the type or form of the electronic device ED.

FIG. 1B illustrates augmented reality (AR) glasses as an example of a wearable device. An electronic device ED may include glasses GR and a frame FR mounted on the glasses GR. The frame FR may accommodate other modules described with reference to FIG. 1A including the display panel 141 described with refence to FIG. 1A. A light guide LG, which guides an image generated from the display panel 141, may also be mounted on the frame FR.

The glasses GR may be worn on a user's head. Because the augmented reality (AR) glasses are described as an example of a wearable device, a structure on which the frame FR is mounted is described as glasses. The structure may be changed depending on a type of the wearable device. In addition, the structure may be omitted depending on a type of the electronic device ED.

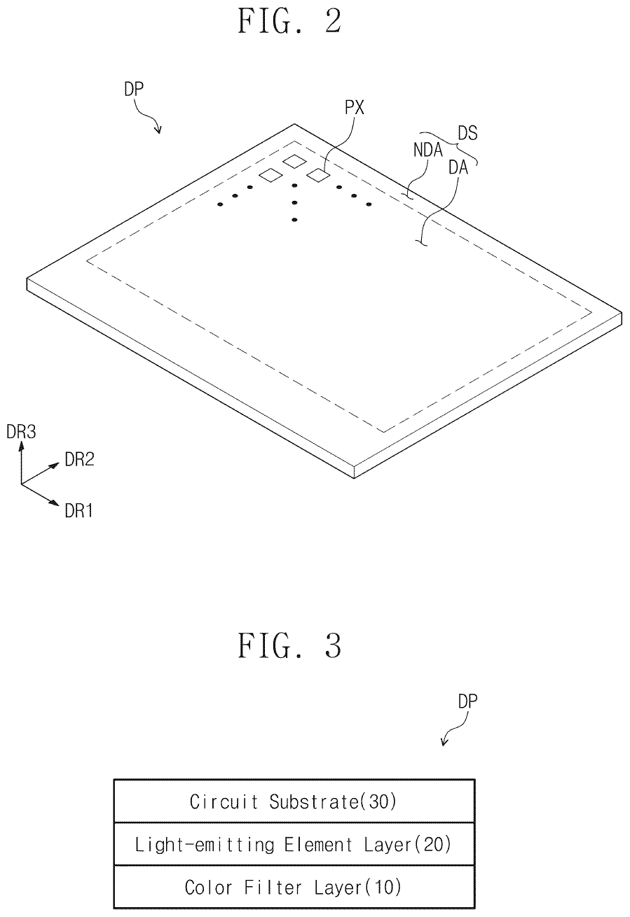

FIG. 2 is a perspective view of a display panel DP according to one or more embodiments of the present disclosure. FIG. 3 is a cross-sectional view of a display panel DP according to one or more embodiments of the present disclosure. Hereinafter, the display panel 141 in FIG. 1A will be described below as a display panel DP.

Referring to FIG. 2, the display panel DP according to one or more embodiments of the present disclosure includes a display surface DS that is substantially parallel to a plane defined by a first direction DR1 and a second direction DR2. An image is displayed through the display surface. A normal direction of the display surface is defined as a third direction DR3. In this specification, the meaning of “when viewed on a plane” is defined as a state viewed from the third direction DR3.

The display surface DS may include a display region DA, and a non-display region NDA around the display region DA. The display region DA displays an image, and the non-display region NDA does not display an image. The non-display region NDA may surround the display region DA, but one or more embodiments of the present disclosure is not limited thereto. The non-display region NDA might not be located at one side of the display region DA.

A plurality of pixels PX may be arranged in the display region DA. The pixels PX may be arranged in a matrix. The pixels PX may each include a pixel circuit and a light-emitting element. The pixels PX may all generate light of the same color. In one or more embodiments of the present disclosure, the pixels PX may include a plurality of groups that generate light of different colors.

FIG. 3 briefly illustrates a cross section of the display panel DP illustrated in FIG. 2.

Referring to FIG. 3, the display panel DP may include a circuit substrate 10, a light-emitting element layer 20, and a color filter layer 30. In one or more embodiments of the present disclosure, the display panel DP may further include a lens layer located on the color filter layer 30 (as used herein, “located on” may mean “above”).

The circuit substrate 10 may include a pixel circuit. The pixel circuit may control an operation of a light-emitting element of the light-emitting element layer 20 to be described later. The pixel circuit may include at least one transistor. The circuit substrate 10 may include a CMOS wafer. The CMOS wafer may include an nMOSFET (NMOS) and a pMOSFET (PMOS) that are complementarily connected. Multiple pixel regions are regularly arranged on the CMOS wafer, and a respective pixel circuit is located in each pixel region.

The light-emitting element layer 20 may include a light-emitting element electrically connected to the pixel circuit. The light-emitting element may include an organic light-emitting element, but is not necessarily limited thereto. The light-emitting element may generate first color light, second color light, and third color light. The first color light, the second color light, and the third color light may be mixed to form white light. However, one or more embodiments of the present disclosure is not limited thereto, and the light-emitting element may generate the first color light only.

The color filter layer 30 may include a color filter. The color filter may transmit light in a corresponding wavelength band among the light generated from the light-emitting element, and may absorb light in wavelength bands other than the corresponding wavelength band. The color filter layer 30 may include a plurality of color filters. The color filter layer 30 may include a first color filter that selectively transmits the first color light, a second color filter that selectively transmits the second color light, and a third color filter that selectively transmits the third color light.

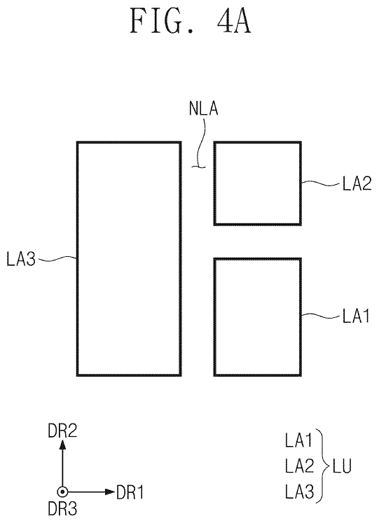

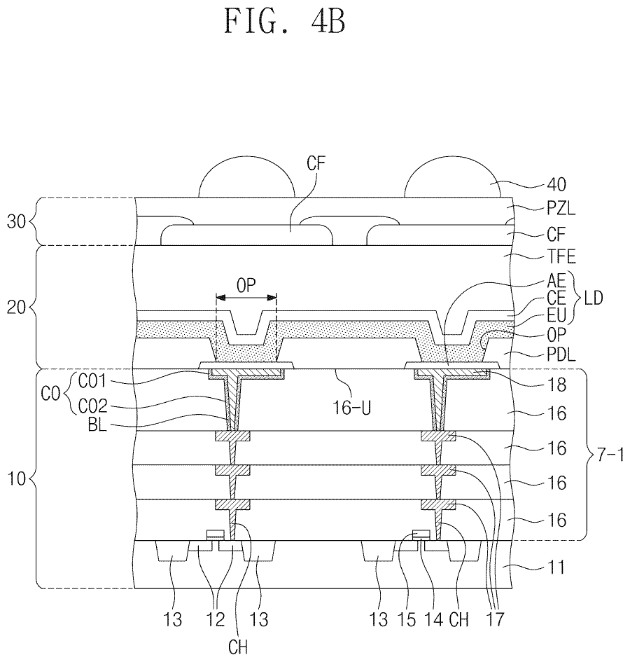

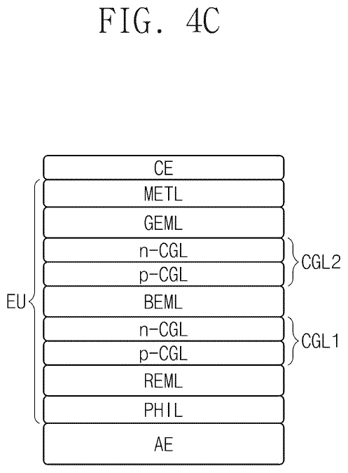

FIG. 4A is a plan view of a display region DA according to one or more embodiments of the present disclosure. FIG. 4B is a cross-sectional view of a display region DA according to one or more embodiments of the present disclosure. FIG. 4C is a cross-sectional view of a light-emitting element LD according to one or more embodiments of the present disclosure.

FIG. 4A illustrates unit regions LU repeatedly arranged in the display region DA in FIG. 2. The unit region LU may include a first emission region LA1, a second emission region LA2, and a third emission region LA3. A first pixel light-emitting element, a second pixel light-emitting element, and a third pixel light-emitting element may be respectively located in the first emission region LA1, the second emission region LA2, and the third emission region LA3.

First color light, second color light, and third color light may be provided to the outside through the first emission region LA1, the second emission region LA2, and the third emission region LA3. The first pixel light-emitting element, the second pixel light-emitting element, and the third pixel light-emitting element may respectively generate the first color light, the second color light, and the third color light. A first color filter, a second color filter, and a third color filter, which are respectively located in the first emission region LA1, the second emission region LA2, and the third emission region LA3, selectively transmit the first color light, the second color light, and the third color light. In one or more embodiments of the present disclosure, light-emitting elements that generate light of different colors may be respectively located in the first emission region LA1, the second emission region LA2, and the third emission region LA3.

Red light may be provided to the outside of a display panel DP through the first emission region LA1, green light may be provided to the outside of the display panel DP through the second emission region LA2, and blue light may be provided to the outside of the display panel DP through the third emission region LA3. An arrangement of the first emission region LA1, the second emission region LA2, and the third emission region LA3, which are illustrated in FIG. 4A, an area ratio of the first emission region LA1, the second emission region LA2, and the third emission region LA3, and shapes of the first emission region LA1, the second emission region LA2, and the third emission region LA3 are merely an example, and one or more embodiments of the present disclosure is not limited thereto.

In FIG. 4A, the first emission region LA1 and the second emission region LA2 may be at a right or left side of the third emission region LA3, and the first emission region LA1 and the second emission region LA2 may be arranged in a second direction DR2. Among the first emission region LA1, the second emission region LA2, and the third emission region LA3, the third emission region LA3 may have the greatest area, and the second emission region LA2 may have the smallest area. The first emission region LA1, the second emission region LA2, and the third emission region LA3 may each have a rectangular shape. A non-emission region NLA may be located between the first emission region LA1, the second emission region LA2, and the third emission region LA3. In one or more embodiments, the non-emission region NLA may be located between the adjacent unit regions LU.

FIG. 4B is a cross-sectional view corresponding to two adjacent emission regions among the first emission region LA1, the second emission region LA2, and the third emission region LA3.

FIG. 4B illustrates, in detail, a cross section of the display panel DP illustrated in FIG. 3. The display panel DP may include a circuit substrate 10, a light-emitting element layer 20, a color filter layer 30, and a lens layer 40. The lens layer 40 is additionally illustrated as compared to FIG. 3.

The circuit substrate 10 may be a complementary metal oxide semiconductor (CMOS) circuit substrate 10. The circuit substrate 10 includes a semiconductor substrate 11. The semiconductor substrate 11 may be a silicon substrate, a germanium substrate, or a silicon-germanium substrate.

Source/drain regions 12 may each be a respective region doped with a dopant. A pair of the source/drain regions 12 may define a transistor with a gate 15, to be described in further detail later. The source/drain regions 12 may become a source of the transistor or a drain of the transistor according to a signal flow. That is, when one of the source/drain regions 12 is the source region 12, the other one may be the drain region 12.

Shallow trench isolation (STI) regions 13 may further be defined in the semiconductor substrate 11. The STI regions 13 may reduce or prevent a leakage current by isolating the transistor. STI regions 13 may be located differently depending on a design of a pixel circuit.

A wiring layer 11-1 is located on (e.g., above) the semiconductor substrate 11. The wiring layer 11-1 may include at least one of insulation layers 14 and 16 and at least one of conductive patterns 15 and 17. It is illustrated that the wiring layer 11-1 includes five insulation layers 14 and 16 and five conductive patterns 15 and 17. The plurality of insulation layers 14 and 16 may include a silicon carbon nitride (SiCN)-based inorganic film or a silicon oxide (SiO)-based inorganic film. The plurality of conductive patterns 15 and 17 may be formed of any one among copper (Cu), aluminum (Al), tungsten (W), molybdenum (Mo), chrome (Cr), gold (Au), titanium (Ti), nickel (Ni), and/or neodymium (Nd), or formed of an alloy including any one thereamong.

A gate insulation layer 14 and gates 15 are located on/above the semiconductor substrate 11. The gates 15 may contain metal. The gates 15 are each located corresponding to a pair of the source/drain regions 12. The gate insulation layer 14 may include insulation patterns located corresponding to the gates 15.

A plurality of intermediate insulation layers 16 are located on the semiconductor substrate 11. Contact holes CH and CO are defined in the intermediate insulation layers 16. The uppermost intermediate insulation layer 16 among the intermediate insulation layers 16 is defined as a base insulation layer, and an opening formed in the base insulation layer is defined as a contact opening CO.

The conductive pattern 17 is located in each of the contact holes CH of the intermediate insulation layers 16. The conductive pattern 17 may be connected to the conductive pattern 17 located thereunder. The conductive pattern 17 located at the lowermost may be directly connected to the source/drain regions 12. The conductive pattern 17 may be defined as a contact electrode.

An upper surface of the conductive pattern 17 may define the same plane as an upper surface of the intermediate insulation layers 16 (or a surface continuing from the upper surface of the intermediate insulation layers 16). Such a conductive pattern 17 may be formed through a chemical/physical polishing process, for example, a damascene process.

The contact opening CO formed in the base insulation layer 16 may be divided into two regions. The contact opening CO may include a first region CO1 that has a relatively large width, and a second region CO2 that continues from the first region CO1, that is located under the first region CO1, and that has a relatively small width. The first region CO1 is not necessarily limited to have a constant width in a thickness direction, and the second region CO2 is not necessarily limited to have a constant width in the thickness direction. Nevertheless, a variance in the width between the first region CO1 and the second region CO2 is significantly greater than a variance in the width within the first region CO1 or a variance in the width within the second region CO2. A shape of the contact opening CO is related to a manufacturing process and will be described in further detail later.

A conductive pattern is located inside the contact opening CO. This conductive pattern may be defined as a reflective conductive pattern 18. The reflective conductive pattern 18 may have substantially the same shape as the contact opening CO. A width (or a planar area) of a portion located in the first region CO1 may be relatively greater, and a width (or a planar area) of a portion located in the second region CO2 may be relatively smaller.

It is illustrated that the contact opening CO is formed in one intermediate insulation layer, but is not limited thereto. In one or more embodiments of the present disclosure, the contact opening CO may also be formed in two or more intermediate insulation layers.

A barrier layer BL may further be located on an inner surface of the base insulation layer 16 that defines the contact opening CO. That is, the barrier layer BL may further be located between the reflective conductive pattern 18 and the inner surface of the base insulation layer 16. The barrier layer BL might not be located on, or may be omitted from above, an upper surface of the base insulation layer 16. This is related to a manufacturing process and will be described in detail later.

The barrier layer BL may include a barrier metal layer and/or a barrier metal nitride layer. The barrier metal layer may be directly located on the inner surface of the base insulation layer 16, and the barrier metal nitride layer may be located on the barrier metal layer.

The barrier metal layer improves adhesion of the reflective conductive pattern 18, and the barrier metal nitride layer reduces or prevents diffusion of atoms of the reflective conductive pattern 18. The barrier metal layer may include titanium or tantalum. The barrier metal nitride layer may include a titanium nitride layer or a tantalum nitride layer. For example, the barrier layer BL may include a titanium layer, and a titanium nitride layer located on the titanium layer. In addition, the barrier layer BL may include a tantalum layer, and a tantalum nitride layer located on the tantalum layer.

The reflective conductive pattern 18 electrically connects the conductive pattern 17 thereunder and a first electrode thereabove, to be described in further detail later. In addition, the reflective conductive pattern 18 may serve as a reflection layer of a light-emitting element to be described later. The light-emitting element uses a resonance phenomenon so as to increase emission efficiency of light generated from an emission unit. Two reflection layers are located on two sides of the emission unit so as to generate such a resonance phenomenon. Among the two sides, a translucent reflection layer is located on the side where light passes through, and an opaque reflection layer with high reflectance is located on the other side. The aforementioned reflective conductive pattern 18 serves as the opaque reflection layer.

A material of the reflective conductive pattern 18 is not particularly limited, and the material may have relatively high conductivity and relatively high reflectance.

The reflective conductive pattern 18 may include copper (Cu) or tungsten (W), and may include silver (Ag), which has particularly high reflectance. The reflective conductive pattern 18 may include an alloy containing copper (Cu), tungsten (W), or silver (Ag).

An upper surface of the reflective conductive pattern 18 may define the same plane as (e.g., may be substantially level with, or even with) an upper surface of the base insulation layer 16 (or a surface continuing from the upper surface of the base insulation layer 16). Such a reflective conductive pattern 18 may be formed through a chemical/physical polishing process, for example, a damascene process.

A light-emitting element LD and a pixel definition layer PDL are located on the base insulation layer 16. The light-emitting element LD may include a first electrode AE, an emission unit EU located on the first electrode AE, and a second electrode CE. The first electrode AE may be an anode, and a second electrode CE may be a cathode.

The first electrode AE may be directly located on the base insulation layer 16, and may be directly located on the reflective conductive pattern 18. The first electrode AE may be in contact with an upper surface 16-U of the base insulation layer 16 and an upper surface of the reflective conductive pattern 18.

A width of the first electrode AE may be greater than a width of the reflective conductive pattern 18. In other words, a planar area of the first electrode AE may be greater than a planar area of the reflective conductive pattern 18 (e.g., in plan view). The reflective conductive pattern 18 is located inside the first electrode AE on a plane to secure sufficient reflection efficiency.

The width of the reflective conductive pattern 18 may be measured as the upper surface of the reflective conductive pattern 18, and the width of the first electrode AE may be measured as a lower surface of the first electrode AE that contacts the reflective conductive pattern 18. The width of the reflective conductive pattern 18 that is measured on the upper surface of the reflective conductive pattern 18 may be substantially the same as a width of the contact opening CO that is measured on the upper surface of the base insulation layer 16. It may be sufficient if the aforementioned widths are measured in the same direction, noting that the widths are not limited to the widths in a corresponding direction.

The first electrode AE might not include an additional reflection layer. As mentioned above, that is because the reflective conductive pattern 18 corresponds to the reflection layer of the first electrode AE. The first electrode AE may be a transparent electrode.

The first electrode AE may include a transparent conductive oxide pattern. The transparent conductive oxide pattern may include indium tin oxide (ITO), indium zinc oxide (IZO), indium gallium zinc oxide (IGZO), zinc oxide (ZnOx), indium oxide (In₂O₃), or aluminum doped zinc oxide (AZO), which facilitates hole injection. The first electrode AE may have a single-or multi-layered structure.

The pixel definition layer PDL is located on the base insulation layer 16. The pixel definition layer PDL may be an organic layer. The single-layered pixel definition layer PDL is illustrated, but one or more embodiments of the present disclosure is not limited thereto. An opening OP that partially exposes the first electrode AE is defined in the pixel definition layer PDL.

The opening OP substantially defines a corresponding emission region among the emission regions LA1, LA2, and LA3 in FIG. 4A. The opening OP is located inside the reflective conductive pattern 18 on a plane/in plan view to align an emission region of the emission unit EU with a reflection region of the reflective conductive pattern 18. The light generated within the emission regions LA1, LA2, and LA3 may be sufficiently reflected at the reflective conductive pattern 18 having a greater area. A width of the opening OP may be less than a width of the reflective conductive pattern 18. The width of the opening OP is measured on an upper surface of the first electrode AE exposed from the opening OP.

The emission unit EU is located on the first electrode AE and the pixel definition layer PDL. The second electrode CE is located on the emission unit EU. The emission unit EU of the light-emitting elements LD may have an integrated shape, and the second electrode CE of the light-emitting elements LD may have an integrated shape. The emission unit EU and the second electrode CE may overlap the first to third emission regions LA1, LA2, and LA3 and the non-emission region NLA in FIG. 4A in common.

A thin-film encapsulation layer TFE is located on the emission unit EU. The thin-film encapsulation layer TFE may protect the light-emitting element layer 20 from moisture, oxygen, and foreign matters, such as dust particles. The encapsulation layer TFE may include at least one inorganic film (hereinafter, an inorganic encapsulation film). In addition, the encapsulation layer TFE may further include at least one organic film (hereinafter, an organic encapsulation film). The thin-film encapsulation layer TFE may include an inorganic encapsulation layer, an organic encapsulation layer, and an inorganic encapsulation layer that are sequentially stacked, but the layers that constitute the thin-film encapsulation layer TFE are not limited thereto.

A color filter layer CFL may be located on the thin-film encapsulation layer TFE. The color filter layer CFL may include a plurality of color filters CF. The plurality of color filters CF may include a first color filter corresponding to the first emission region LA1 in FIG. 4A, a second color filter corresponding to the second emission region LA2, and a third color filter corresponding to the third emission region LA3. The first color filter transmits the first color light among first color light, second color light, and third color light generated from the emission unit EU. The second color filter transmits the second color light among the first color light, the second color light, and the third color light generated from the emission unit EU. The third color filter transmits the third color light among the first color light, the second color light, and the third color light generated from the emission unit EU.

The color filter layer CFL may include a planarization layer PZL located on the color filters CF. The planarization layer PZL may include an organic material. In one or more embodiments, the color filter layer CFL may further include a light-shielding pattern.

The lens layer 40 may be located on the color filter layer CFL. The lens layer 40 may include a plurality of lens patterns. The lens patterns may be located corresponding to the respective first to third emission regions LA1, LA2, and LA3 in FIG. 4A, and may be spaced apart from each other.

Referring to FIG. 4C, an emission unit EU may include a hole injection layer PHIL located on a first electrode AE, a first light-emitting layer REML, a first charge generation layer CGL1, a second light-emitting layer BEML, a second charge generation layer CGL2, a third light-emitting layer GEML, and an electron transport layer METL. The hole injection layer PHIL and the electron transport layer METL may be omitted in one or more embodiments of the present disclosure.

The hole injection layer PHIL may include a hole injection/transport material doped with a P-type dopant. The electron transport layer METL may include an electron injection/transport material that contains metal. The first charge generation layer CGL1 and the second charge generation layer CGL2 may each include a first-type charge generation layer nCGL and a second-type charge generation layer pCGL, which are stacked. The first-type charge generation layer nCGL may be an n-type charge generation layer, and the second-type charge generation layer pCGL may be a p-type charge generation layer.

The first light-emitting layer REML may generate first color light, the second light-emitting layer BEML may generate second color light, and the third light-emitting layer GEML may generate third color light. The first color light may be longer in wavelength than the second color light and the third color light. The third color light may be shorter in wavelength than the first color light and the second color light. The first color light may be red light, the second color light may be green light, and the third color light may be blue light.

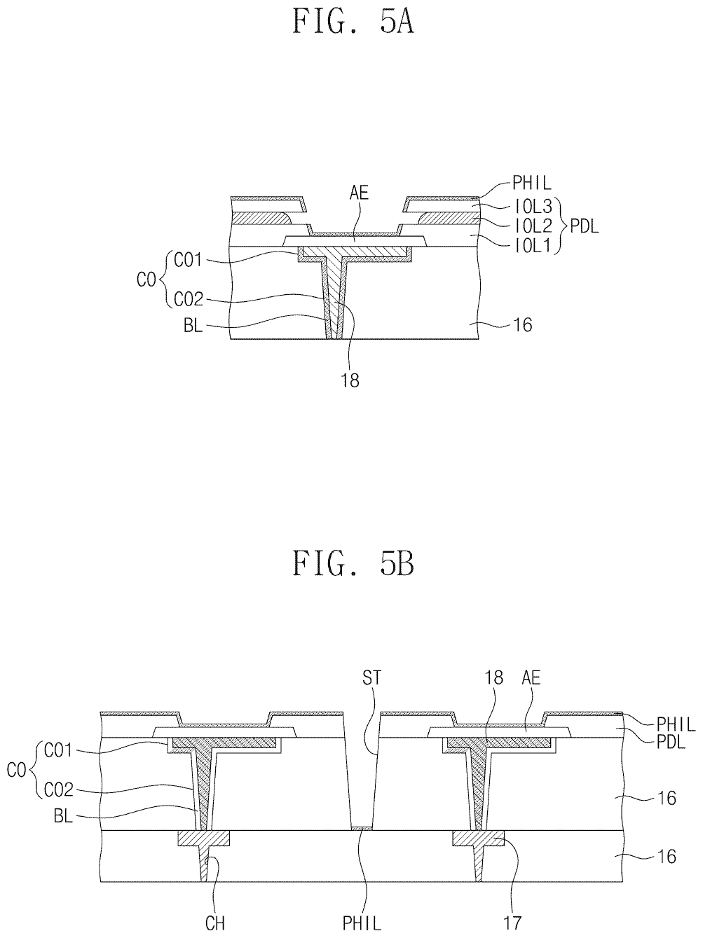

FIGS. 5A and 5B are enlarged partial cross-sectional views of a display panel DP according to one or more embodiments of the present disclosure.

As illustrated in FIG. 5A, a pixel definition layer PDL may include a first inorganic layer IOL1, a second inorganic layer IOL2 that contains a different material from the first inorganic layer IOL1, and a third inorganic layer IOL3 that is located on the second inorganic layer IOL2. An inorganic material of the second inorganic layer IOL2 may have a higher etch rate than an inorganic material of the first inorganic layer IOL1 and an inorganic material of the third inorganic layer IOL3. For example, the second inorganic layer IOL2 may include silicon nitride, and the first inorganic layer IOL1 and the third inorganic layer IOL3 may include silicon oxide. In one or more embodiments of the present disclosure, the first inorganic layer IOL1, the second inorganic layer IOL2, and the third inorganic layer IOL3 may include inorganic materials with different etch rates.

The third inorganic layer IOL3 may protrude more than, or may extend beyond or may extend further than, the second inorganic layer IOL2 on a plane to define a tip structure. The first inorganic layer IOL1 may also protrude more than the second inorganic layer IOL2 on a plane. An inner edge of the tip structure may define a closed line on a plane. On a plane, the tip structure may be located around an opening OP, and may surround the opening OP (in plan view).

FIG. 5A illustrates a hole injection layer PHIL of the emission unit EU illustrated in FIG. 4. The hole injection layer PHIL may have greater electrical conductivity than other layers of the emission unit EU. The hole injection layer PHIL may be disconnected by the tip structure. Accordingly, a leakage current between the adjacent light-emitting elements LD (see FIG. 4B) may be reduced or prevented by the hole injection layer PHIL.

As illustrated in FIG. 5B, a trench or slit may be defined in a pixel definition layer PDL and a base insulation layer 16. FIG. 5B illustrates a slit ST, that is, an opening that has a shape penetrating (e.g., completely penetrating) the pixel definition layer PDL and the base insulation layer 16. In one or more embodiments of the present disclosure, an opening that penetrates the pixel definition layer PDL and eliminates only a portion of the base insulation layer 16 may be defined as the trench.

The trench or slit is located outside of a first electrode AE on a plane/in plan view. FIG. 5B illustrates one slit ST located between the first electrodes AE, but a plurality of slits ST may be located between the first electrodes AE, in one or more embodiments. Referring to FIG. 4A, at least one slit ST extending in a second direction DR2 may be located between the third emission region LA3 and first and second emission regions LA1 and LA2.

The trench or slit ST may have a closed line shape on a plane. Referring to FIG. 4A, trenches or slits surrounding each of the first emission region LA1, the second emission region LA2, and the third emission region LA3 may be located in a display region DA.

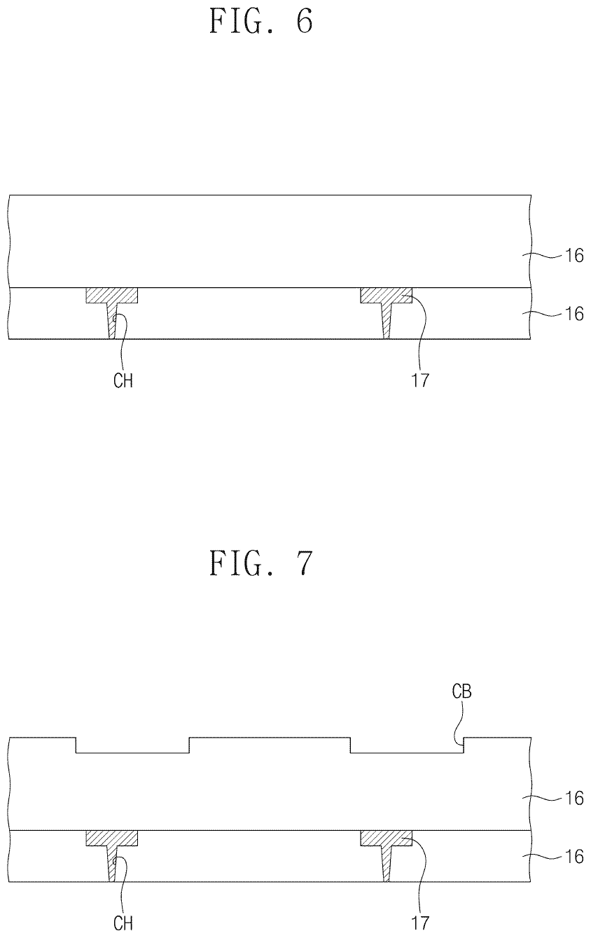

FIGS. 6 to 14 are cross-sectional views illustrating a method of manufacturing a display panel DP according to one or more embodiments of the present disclosure. Hereinafter, a detailed description of the components that have been described with reference to FIG. 4B will be omitted.

As illustrated in FIG. 6, a base insulation layer 16 is formed on an intermediate insulation layer 16 to cover a conductive pattern 17. The base insulation layer 16 may be formed by depositing an inorganic material. Unlike FIG. 4B, some components of the circuit substrate 10 are omitted from FIG. 6 and subsequent drawings.

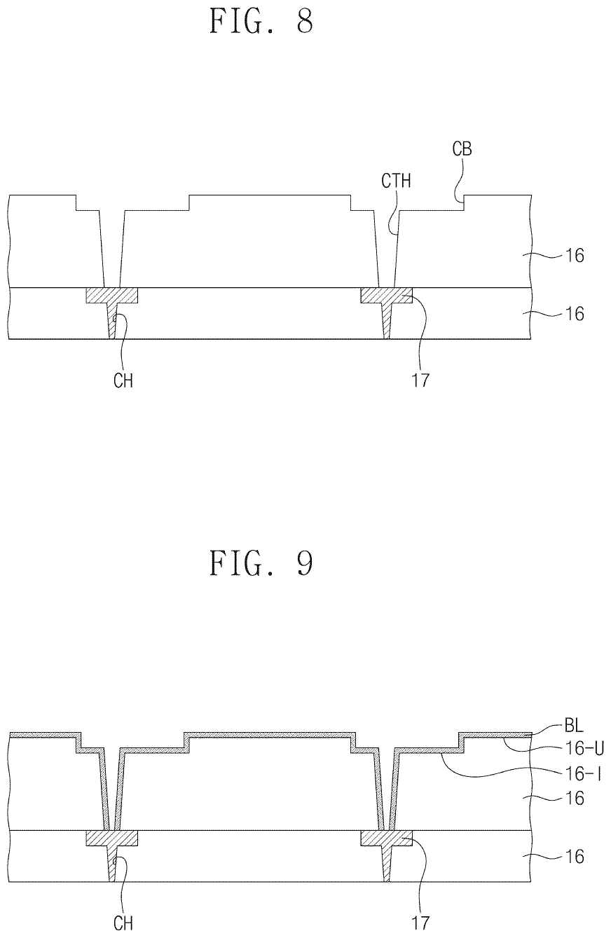

As illustrated in FIGS. 7 and 8, a contact opening CO is formed in the base insulation layer 16. A method of forming the contact opening CO described with reference to FIGS. 7 and 8 is merely an example, and one or more embodiments of the present disclosure is not limited thereto.

As illustrated in FIG. 7, a cavity CB is formed in the base insulation layer 16. After forming a photoresist layer on the base insulation layer 16, exposure and development processes are performed. Then, the cavity CB is formed through an etching process. The cavity CB corresponds to the first region CO1 of the contact opening CO illustrated in FIG. 4A.

As illustrated in FIG. 8, a contact hole CTH that continues from the cavity CB and penetrates the base insulation layer 16 is formed. The contact hole CTH is formed in a region overlapping the cavity CB. After forming a photoresist layer on the base insulation layer 16, exposure and development processes are performed. Then, the contact hole CTH is formed through an etching process. The contact hole CTH corresponds to the second region CO2 of the contact opening CO illustrated in FIG. 4A. As seen in the cavity CB and the contact hole CTH, etching regions with different areas may be determined according to a mask pattern formed from the photoresist layer.

As illustrated in FIG. 9, a barrier layer BL is formed on the base insulation layer 16. The barrier layer BL may be formed through a deposition process. The barrier layer BL is formed on an upper surface 16-U of the base insulation layer 16 and on an inner surface 16-I of the base insulation layer 16 that defines the contact opening OP.

After forming a barrier metal layer on the base insulation layer 16, a barrier metal nitride layer may be formed on the barrier metal layer. At least one of the barrier metal layer or the barrier metal nitride layer may be omitted in one or more embodiments of the present disclosure. The barrier layer BL might not be formed in one or more embodiments of the present disclosure.

As illustrated in FIG. 10, a reflective conductive layer RL is formed on an inner surface 16-I of the contact opening OP and on the upper surface 16-U of the base insulation layer 16. The reflective conductive layer RL that contains copper (Cu), tungsten (W), silver (Ag), or an alloy thereof may be formed through an electroplating process. When the barrier layer BL in FIG. 9 is not formed, the reflective conductive layer RL might not be in contact with the base insulation layer 16.

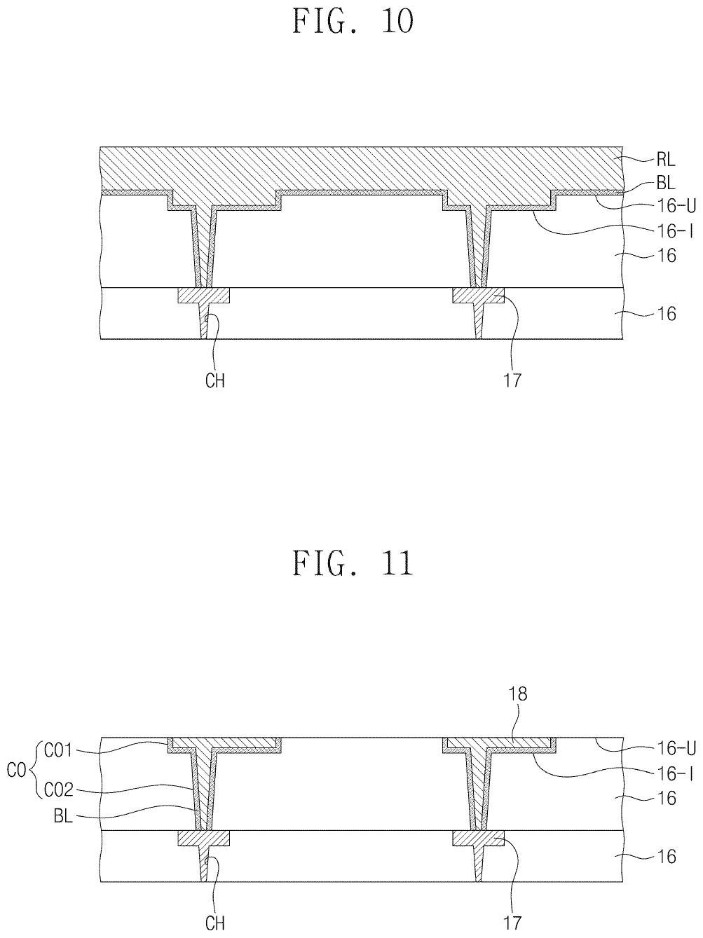

Next, as illustrated in FIG. 11, chemical-mechanical polishing is performed. A thickness of the reflective conductive layer RL is decreased. The reflective conductive layer RL located on the upper surface 16-U of the base insulation layer 16 may be removed by the chemical-mechanical polishing. A reflective conductive pattern 18 located inside the contact opening CO may be formed from the reflective conductive layer RL through the chemical-mechanical polishing.

In the chemical-mechanical polishing step, a portion of the barrier layer BL may also be removed. A portion of the barrier metal layer located on the upper surface of the base insulation layer 16 and a portion of the barrier metal nitride layer may be removed. FIG. 11 illustrates a state in which a portion of the barrier layer BL located on the upper surface of the base insulation layer 16 is removed.

The reflective conductive pattern 18 may be formed from the reflective conductive layer RL through the chemical-mechanical polishing, thereby improving reliability of the reflective conductive pattern 18. When the reflective conductive layer RL including the aforementioned metal (especially, silver (Ag)) is patterned in high resolution through a dry etching process or a wet etching process, a process variation may be greatly increased. That is, the reflective conductive patterns 18 may be formed to have different areas, or different thicknesses. In addition, due to residual components, a short circuit defect may occur between the reflective conductive patterns 18 that are adjacent to each other. However, through the aforementioned process, the reflective conductive pattern 18, which is embedded in the base insulation layer 16, may be formed in high resolution.

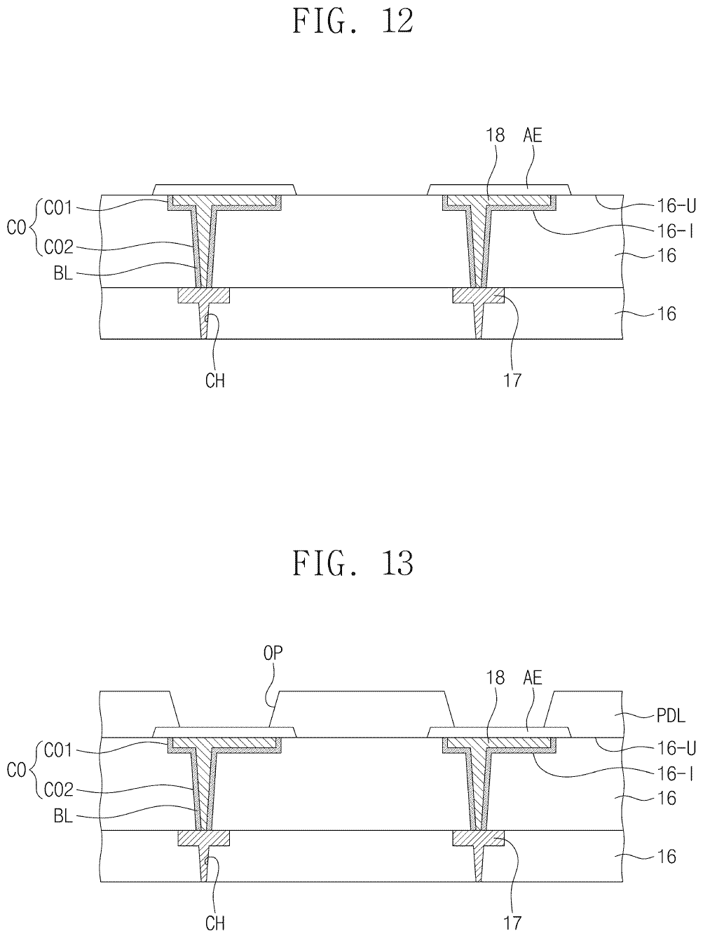

Subsequently, as illustrated in FIG. 12, a first electrode AE aligned with the reflective conductive pattern 18 is formed. After forming a transparent conductive oxide layer on the base insulation layer 16, the transparent conductive oxide layer is patterned through a photolithography process.

Afterwards, as illustrated in FIG. 13, a pixel definition layer PDL is formed on the base insulation layer 16. After forming an organic layer, an opening OP may be formed through exposure and development processes. In one or more embodiments of the present disclosure, after forming an inorganic layer, the opening OP may be formed through a photolithography process. To form the pixel definition layer PDL illustrated in FIG. 5A, a first inorganic layer IOL1, a second inorganic layer IOL2, and a third inorganic layer IOL3 are deposited sequentially, and then the photolithography process is performed. When an etch rate varies depending on etching fluid (e.g., when the second inorganic layer IOL2 is etched more than the first inorganic layer IOL1 and/or the third inorganic layer IOL3), a tip structure may be formed.

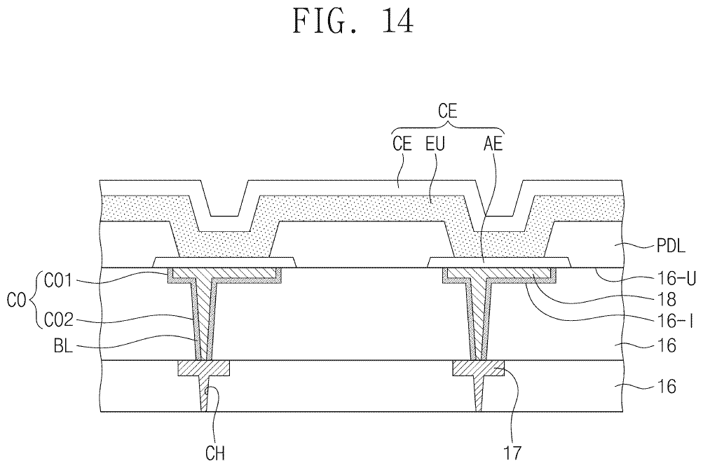

Thereafter, as illustrated in FIG. 14, an emission unit EU is formed on the first electrode AE and the pixel definition layer PDL, and a second electrode CE is formed. The emission unit EU and the second electrode CE may be formed through a typical process.

According to the description above, a light-emitting element with a simplified electrode structure may be provided. A connection electrode of a driving circuit layer may be used as a reflection layer of the light-emitting element, and thus the structure of the electrode located at a low position of the light-emitting element may be simplified.

In addition, a leakage current between the adjacent light-emitting elements may be reduced.

In the above, description has been made with reference to embodiments of the present disclosure, but those skilled or of ordinary skill in the art may understand that various modifications and changes may be made to the present disclosure insofar as such modifications and changes do not depart from the aspects of the present disclosure set forth in the claims to be described later.

Therefore, the technical scope of the present disclosure is not limited to the contents stated in the detailed description of the specification, but should be determined by the claims, with functional equivalents thereof to be included therein.

What is claimed is:

1. A display panel comprising:
a complementary metal oxide semiconductor (CMOS) circuit substrate comprising:
a semiconductor substrate; and
a wiring layer above the semiconductor substrate, and comprising a conductive pattern, a base insulation layer above the conductive pattern, and a reflective conductive pattern connected to the conductive pattern through a contact opening penetrating the base insulation layer;
a first light-emitting element above the CMOS circuit substrate, and comprising a first electrode contacting the reflective conductive pattern, a second electrode above the first electrode, and an emission unit between the first electrode and the second electrode; and
a pixel definition layer above the wiring layer, and defining an opening exposing the first electrode and having a width at an upper surface of the first electrode that is less than a width of the contact opening at an upper surface of the base insulation layer.

2. The display panel of claim 1, wherein the first electrode contacts an upper surface of the base insulation layer.

3. The display panel of claim 1, wherein the first electrode comprises a transparent conductive oxide pattern.

4. The display panel of claim 1, wherein a width of a lower surface of the first electrode is greater than the width of the contact opening, and
wherein an upper surface of the reflective conductive pattern is inside the first electrode in plan view.

5. The display panel of claim 1, wherein an upper surface of the reflective conductive pattern is substantially level with an upper surface of the base insulation layer.

6. The display panel of claim 1, further comprising a barrier layer between the reflective conductive pattern and an inner surface of the base insulation layer defining the contact opening,
wherein the barrier layer comprises a barrier metal layer and a barrier metal nitride layer.

7. The display panel of claim 6, wherein the barrier metal layer comprises titanium or tantalum.

8. The display panel of claim 6, wherein the barrier layer is omitted from above an upper surface of the base insulation layer.

9. The display panel of claim 1, wherein the reflective conductive pattern comprises silver.

10. The display panel of claim 1, wherein the pixel definition layer comprises:
a first inorganic layer;
a second inorganic layer comprising a different material from the first inorganic layer; and
a third inorganic layer above the second inorganic layer, comprising a different material from the second inorganic layer, and extending further than the second inorganic layer in plan view to define a tip structure.

11. The display panel of claim 1, wherein the pixel definition layer and the base insulation layer define a trench or a slit outside the first electrode in plan view.

12. The display panel of claim 11, wherein the trench or the slit has a closed line shape in plan view.

13. The display panel of claim 1, wherein the emission unit comprises:
a first light-emitting layer configured to generate first color light;
a first charge generation layer above the first light-emitting layer;
a second light-emitting layer above the first charge generation layer, and configured to generate second color light;
a second charge generation layer above the second light-emitting layer; and
a third light-emitting layer above the second charge generation layer, and configured to generate third color light.

14. The display panel of claim 1, further comprising a second light-emitting element above the CMOS circuit substrate, and comprising a first electrode spaced from the first electrode of the first light-emitting element, an emission unit integrated with the emission unit of the first light-emitting element, and a second electrode integrated with the second electrode of the first light-emitting element.

15. The display panel of claim 1, further comprising:
a thin-film encapsulation layer above the first light-emitting element;
a color filter above the thin-film encapsulation layer; and
a lens above the color filter.

16. The display panel of claim 1, wherein a source region and a drain region are defined in the semiconductor substrate, and
wherein the wiring layer comprises a gate above the semiconductor substrate between the source region and the drain region in plan view, at least one insulation layer above the gate, and at least one contact electrode connected to the source region or to the drain region through a contact hole in the at least one insulation layer.

17. A method of manufacturing a display panel, the method comprising:
forming a contact opening in a base insulation layer;
forming a reflective conductive layer inside the contact opening above an upper surface of the base insulation layer;
performing chemical-mechanical polishing to form a reflective conductive pattern inside the contact opening and omitted from above the upper surface of the base insulation layer;
forming a first electrode above the upper surface of the base insulation layer; and
forming a pixel definition layer above the upper surface of the base insulation layer and defining an opening exposing a portion of the first electrode, the opening having a width at an upper surface of the first electrode that is less than a width of the contact opening at an upper surface of the base insulation layer.

18. The method of claim 17, wherein the forming of the contact opening comprises:
forming a cavity in the base insulation layer; and
forming a contact hole from the cavity and penetrating the base insulation layer, the contact hole having a width that is less than a width of the cavity.

19. The method of claim 17, further comprising forming a barrier layer comprising a barrier metal layer and a barrier metal nitride layer above the upper surface of the base insulation layer and an inner surface of the base insulation layer defining the contact opening,
wherein the performing of chemical-mechanical polishing comprises removing a portion of the barrier layer above the upper surface of the base insulation layer.

20. An electronic device comprising:
a display panel;
a frame accommodating the display panel; and
a structure on which the frame is mounted,
wherein the display panel comprises:
a complementary metal oxide semiconductor (CMOS) circuit substrate comprising a semiconductor substrate, and a wiring layer above the semiconductor substrate and comprising a conductive pattern, a base insulation layer on the conductive pattern, and a reflective conductive pattern connected to the conductive pattern through a contact opening in the base insulation layer,
a first light-emitting element above the CMOS circuit substrate, and comprising a first electrode contacting the reflective conductive pattern, a second electrode above the first electrode, and an emission unit between the first electrode and the second electrode, and
a pixel definition layer above the wiring layer, and defining an opening exposing the first electrode and having a width at an upper surface of the first electrode that is less than a width of the contact opening at an upper surface of the base insulation layer.
